(19) United States
(12) Patent Application Publication
(10) Pub. No.: US 2007/0177428 A1
(43) Pub. Date: Aug. 2, 2007

(54) Memory circuit arrangement and method for reading and/or verifying the status of memory cells of a memory cell array

(76) Inventors: Zeev Cohen, Zichron-Yaakov (IL); Volker Pissors, Volkersdorf (DE); Eduardo Maayan, Kfar Saba (IL)

Correspondence Address: SLATER & MATSIL LLP, 17950 PRESTON ROAD, SUITE 1000, DALLAS, TX, 75252, US

(21) Appl. No.: 11/343,279

(22) Filed: Jan. 30, 2006

(51) Int. Cl. G11C 11/34

(52) U.S. Cl. 365/185.22

(57) ABSTRACT

A memory circuit arrangement includes a memory cell array having a plurality of memory cells. A memory read/verify control circuit controls a read operation and/or a verify operation on one or a plurality of memory cells of the memory cell array. The memory read/verify control circuit is adapted to read and/or verify the status of each memory cell of the memory cell array according to read and/or verify instruction information on memory cell level.

### TECHNICAL FIELD

The invention relates to a memory circuit arrangement and a method for reading and/or verifying the status of memory cells of a memory cell array.

### BACKGROUND

Modern non-volatile mass storage in NAND-architecture, as well as in NOR-architecture, provides higher and higher memory capacity and performance together with a low power consumption. However, there is a continuous need in the improvement of all three above-mentioned features. In order to improve these three features, which are highly relevant for the market, innovations are necessary in the design and layout of memory cell arrays.

In a common flash memory cell array, when changing of the status of the memory cells in the memory cell array, the status of the memory cells are usually read multiple times during the status change process in order to ensure that the desired status of the respective memory cell is achieved. In particular each read operation, for example each erase verify operation or each program verify operation causes a current flow through the memory cell array and the usually provided sense amplifiers. This current flow contributes to the undesired power consumption of the chip comprising the flash memory. In flash memories having a high volume, for example in flash memories having a storage capacity of 512 MB and more, a high number of corresponding sense amplifiers is provided. By way of example, 64 to 256 sense amplifiers are provided on the chip and are driven simultaneously.

FIG. 8 shows a process flow diagram 800 that illustrates a programming operation of a flash memory cell array in accordance with the prior art.

As shown in the process flow diagram 800 in FIG. 8, after having started the programming operation (step 801), a word index “w” is set to the value “1” (step 802) and a program pulse index “i” is also set to a value “1” (step 803).

In a first programming step, a first program pulse for programming the memory cells of memory cell word “w” is provided by means of the program control unit (step 804) in order to provide the memory cells of word “w” of the memory cell array with an electrical voltage pulse provided for programming the memory cells according to a predetermined programming instruction.

After having finished the first (in general the i-th) program pulse for word “w”, a verify read step is executed on the memory cell word “w” in the i-th iteration, as shown in step 805.

Then, it is determined as to whether all memory cells of memory cell word “w” have been programmed in a satisfactory manner, in other words, it is determined as to whether all memory cells of memory cell word “w” satisfy a predetermined programming criterion. By way of example, it is determined as to whether each one of the memory cells of memory cell word “w” shows the desired respective threshold voltage (determination step 806).

In case that not all memory cells of memory cell word “w” are finally programmed (“No” in step 806), i.e., in case that they do not have the desired threshold voltage, respectively, a further program pulse is provided, which is shown in FIG. 8 by means of a new program pulse iteration for memory cell word “w,” and which is implemented in the process flow by increasing the program pulse index “i” by one (step 807) and then returning to step 804, in which the i-th program pulse is provided for memory cell word “w”.

This iterative provision of a program pulse and a respective subsequent verify read operation is repeated until all memory cells of the memory cell word “w” are programmed, in other words, until all memory cells of memory cell word “w” fulfill the predefined programming criterion.

In case that all memory cells of memory cell word “w” are considered to be programmed in step 806 (“Yes” in step 806), another determination step is executed (step 808), in which it is determined as to whether all memory cells of the memory cell array have been programmed. In case that not all memory cells have already been programmed (“No” in step 808), the program operation is executed for the next memory cell word “w+1” in the memory cell array, which is shown in FIG. 8 by means of the increase of the memory cell word index “w” by “1” (step 809) and the continuation of the process flow in step 803, in which the program pulse index “i” is reset to the value “1” for the one or plurality of new program pulses for the memory cells of the new memory cell word “w”.

If all memory cells are programmed (“Yes” in step 808), the programming operation is finished and ends in step 810.

It is to be noted that in the common verify read operation, all memory cells of a memory cell word “w” are read, irrespective as to whether one or a plurality of memory cells of this memory cell word “w” has already been successfully programmed or not. This leads to an undesirably high power consumption in read operations.

What is therefore needed is an improved memory device architecture and a corresponding method for reading and/or verifying the status of memory cells of a memory cell array, which provides less power consumption.

### SUMMARY OF THE INVENTION

Embodiments of the present invention provide a new memory circuit arrangement and a method for improved reading and/or verifying the status of memory cells of a memory cell array, which saves power consumption.

The memory circuit arrangement and the method for reading and/or verifying the status of memory cells of a memory cell array, can be designed such that only those memory cells are read and/or verified that have not yet reached the desired memory cell status, in general, which still have to be read and/or verified according to a memory cell read and/or memory cell verify instruction.

In an exemplary embodiment of the invention, the memory circuit arrangement comprises a memory cell array comprising a plurality of memory cells and a memory read/verify control circuit for controlling a read operation and/or a verify operation on one or a plurality of memory cells of the memory cell array, wherein the memory read/verify control circuit is adapted to read and/or verify the status of each memory cell of the memory cell array according to a read and/or verify instruction information on memory cell level.

In an exemplary embodiment of the invention, a method for reading and/or verifying the status of memory cells, of a memory cell array, is provided. A read and/or verify instruction information identifies the memory cells of the memory cell array, which are to be read and/or verified, on memory cell level. The identified memory cells of the memory cell array are read and/or verified according to the instruction information.

Furthermore, an exemplary flash memory circuit arrangement comprises a flash memory cell array that includes a plurality of flash memory cells. A flash memory read/verify control circuit controls a read operation and/or a verify operation on one or a plurality of memory cells of the memory cell array. The memory read/verify control circuit is adapted to read and/or verify the status of each memory cell of the memory cell array according to a bit-level mask including bits. Each of the bits of the bit-level mask is assigned to one memory cell of the memory cell array, respectively. Each bit represents the information as to whether the status of the assigned memory cell should be read and/or verified or not. A memory region stores the bits of the bit-level mask.

These and other features of the invention will be better understood when taken in view of the following drawings and a detailed description.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a portion of an exemplary memory cell array in accordance with the present invention;

FIG. 2 illustrates another exemplary portion of the memory cell array memory circuit arrangement in accordance with the present invention;

FIG. 3 shows a process flow diagram illustrating an exemplary programming operation in accordance with the present invention;

FIG. 4 shows a first part of an exemplary process flow diagram for a programming operation in accordance with the present invention;

FIG. 5 illustrates a second portion of an exemplary process flow diagram for a programming operation in accordance with the present invention;

FIG. 6 illustrates a second exemplary memory circuit arrangement in accordance with the present invention;

FIG. 7 illustrates a third exemplary memory circuit arrangement in accordance with the present invention;

FIG. 8 illustrates a block diagram describing the process flow of a programming operation of a memory cell arrangement in accordance with the prior art.

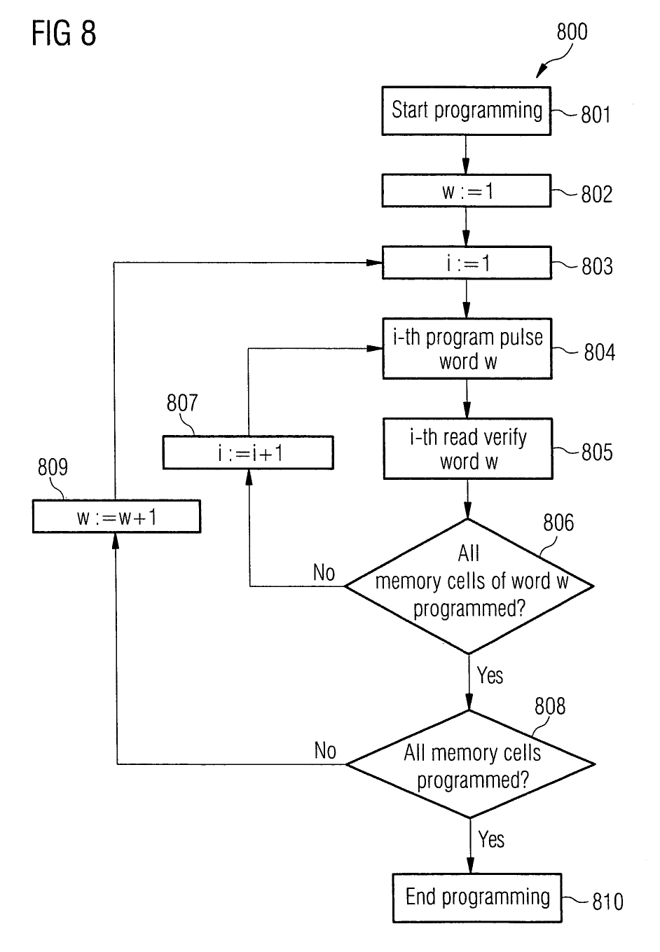

Corresponding numerals and symbols in the different figures refer to corresponding parts unless otherwise indicated. The figures are drawn to clearly illustrate the relevant aspects of the preferred embodiments and are not necessarily drawn to scale.

The following list of reference symbols can be used in conjunction with the figures:
100 Memory circuit arrangement
101 Memory cell array
102 Memory cell
103 Roll memory cell array
104 Column memory cell array
105 Read circuit
106 Read circuit line
107 Sense amplifier
108 Sense amplifier line
109 Databus
110 Databus line
111 Memory read
201 SRAM
202 Flip-flop
300 Block diagram
301 Memory cell word in initial status
302 First program pulse
303 Status memory cell word after application first program pulse
304 Second program pulse
305 Status memory cell word after application second program pulse
306 Third program pulse
307 Status memory cell word after application third program pulse
308 N-th program pulse
309 Status memory cell word after application N-th program pulse
400 Flow diagram
401 Start programming operation
402 w:=1
403 All memory cells programmed?
404 w:=w+1
405 End programming
500 Flow diagram
501 Initialize bit-level mask for word w
502 i:=1
503 i-th program pulse for memory cell word w
504 i-th read/verify memory cell word w according to bit-level mask
505 All memory cells of memory cell word w programmed?
506 Update bit-level mask for memory cell word w
507 i:=i+1
600 Memory circuit arrangement
601 Memory cell array
602 Bit line decoder unit
603 Bit line decoder unit line
604 Sense amplifier
605 Input line sense amplifier
606 Bit line address generator unit
607 First input bit line address generator unit
608 Address counter line
609 Second input bit line address generator unit
610 Mask data line
611 Bit line address line
612 Output bit line generator unit
613 AND gate
614 Output line bit line generator unit
615 Ready signal
616 Third input bit line address generator unit
700 Memory circuit arrangement
701 Bit line driver
702 Voltage regulator unit
703 Bit line driver input line
704 First terminal voltage regulator
705 Second terminal voltage regulator
800 Flow diagram
801 Start programming
802 w:=1
803 i:=1
804 i-th program pulse for memory cell word w
805 i-th read/verify for memory cell word w
806 All memory cells of memory cell word w programmed?
807 i:=i+1
808 All memory cells programmed?
809 w:=w+1
810 End programming

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

According to one aspect of the invention, the memory circuit arrangement comprises a determination unit for determining those memory cells, on which the read operation and/or the verify operation should be performed.

Furthermore, the read and/or verify instruction information may be a bit-level mask including bits, wherein each bit of the bit-level mask is assigned to one memory cell of the memory cell array, respectively, and wherein each bit is representing the information as to whether the status of the assigned memory cell should be read and/or verified or not. This feature allows a very easy and fast approach in order to instruct the memory read/verify control circuit as to which memory cells should be read and/or verified and correspondingly, which components of the memory read/verify control circuit are to be activated and which are to be deactivated.

According to another aspect of the invention, the memory circuit arrangement further comprises a memory region for storing the read and/or verify instruction information, wherein the memory region can be implemented as a random access memory, e.g., as a static random access memory (SRAM). However, it should be noted that any other kind of memory can be used for storing the read and/or verify instruction information, e.g., a non-volatile memory like a flash memory, like a floating gate memory, or a nitrided read only memory (NROM), a magnetoresistive random access memory (MRAM), a phase change memory (PCM), a ferroelectric random access memory (FeRAM) or a dynamic random access memory (DRAM). Storing the read and/or verify instruction information provides the advantage that the read and/or verify instruction information can be read a plurality of times and can also be changed, thereby providing an efficient way of bitwise adapting the read and/or verify instruction information to the respective current status of the memory cell array.

In accordance with another aspect of the invention, a plurality of amplifier circuits is provided, which are coupled to the memory cells of the memory cell array for amplifying the signals read from the memory cell. In an exemplary embodiment of the invention, the amplifier circuits are sense amplifier circuits, wherein each sense amplifier circuit is assigned to one or a predetermined number of memory cells in the memory cell array.

The memory cells may be arranged in columns and rows within the memory cell array, wherein each amplifier circuit may be respectively assigned to all memory cells of one row or to all memory cells of one column, alternatively, to a predetermined number (plurality) of memory cells of a predetermined number (plurality) of rows or to a predetermined number (plurality) of memory cells of a predetermined number (plurality) of columns, e.g., to a respectively predetermined page of memory cells.

In accordance with another aspect of the invention, the memory circuit arrangement further comprises a plurality of storage elements, wherein each storage element is assigned to one amplifier circuit, wherein each storage element stores a portion of the read and/or verify instruction information on the memory cell level.

The storage elements may be arranged as latches or as flipflops. This embodiment provides a very easy and low cost implementation, which achieves a direct control of the respective amplifier circuit in a non-volatile manner, i.e., the control signals on the respective control lines of the data bus do not need to be at high voltage level during the entire operation.

The memory circuit arrangement may be arranged as a flash memory circuit arrangement like a floating gate memory or a nitrided read only memory (NROM), as a magnetoresistive random access memory (MRAM), as a phase change memory (PCM), or as a ferroelectric random access memory (FeRAM).

The flash memory circuit arrangement may thus be arranged as NROM (nitrided read only memory) flash memory circuit arrangement, in other words, the memory cells of the memory cell arrangement may in this case be NROM memory cells.

Generally speaking, the invention is applicable to any memory cell arrangement in which the status of the memory cells of the memory cell array of the memory circuit arrangement is to be determined and in which, without the invention, all memory cells of the group of memory cells are read and/or verified without taking into account, which memory cells already have been programmed, generally speaking, already fulfill a predetermined criterion.

In accordance with one aspect of the method for reading and/or verifying the status of memory cells of a memory cell array, the method further comprises the following steps:

a) executing a programming step on the memory cells of the memory cell according to a programming instruction;

b) executing a verification step on the memory cells of the memory cell array, thereby determining those memory cells, which are sufficiently programmed in the programming step;

c) storing the determined memory cells in the read and/or verify instruction information;

d) executing an additional programming step on the memory cells of the memory cell array according to the programming instruction;

e) executing an additional read and/or verification step on the memory cells of the memory cell array only on the memory cells, which are not yet sufficiently programmed according to the read and/or verify instruction information, thereby determining the memory cells, which are sufficiently programmed in the additional programming step.

In accordance with another aspect of the invention, the steps d) and e) mentioned above, are repeatedly executed and the read and/or verify instructions information is updated after each read and/or verification step.

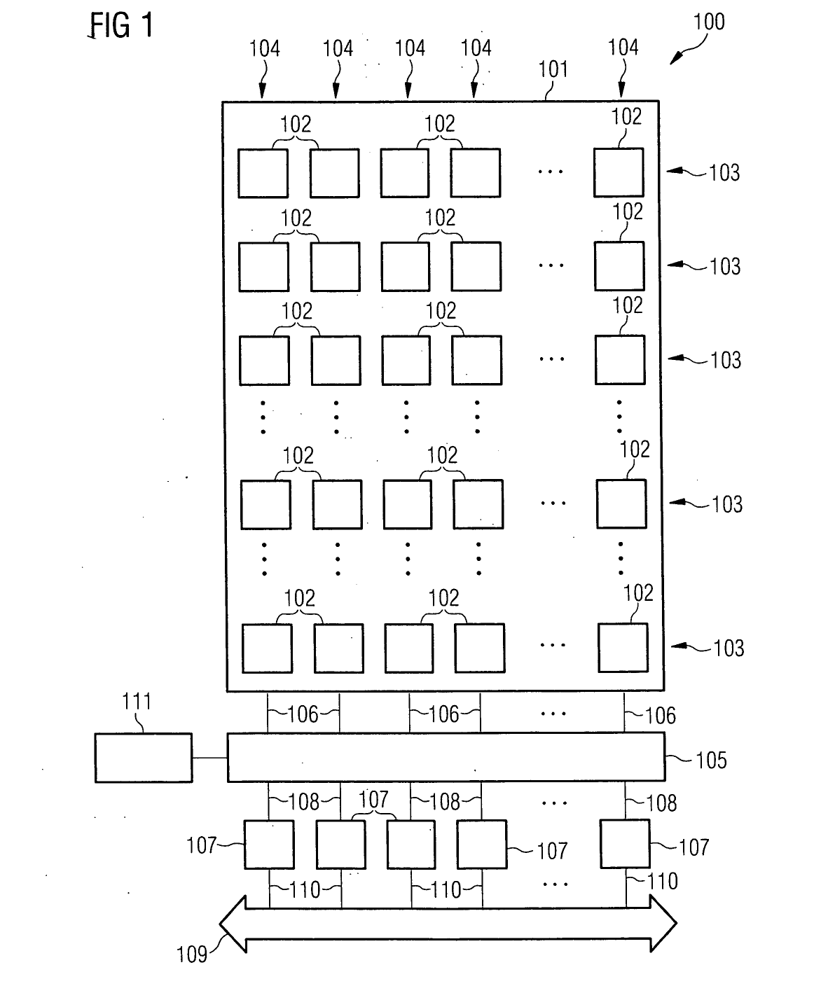

FIG. 1 shows a block diagram 100 illustrating a portion of a memory circuit arrangement. The portion of the memory circuit arrangement shown in FIG. 1 comprises a memory cell array 101 comprising a multiplicity of NROM memory cells 102 being adapted as nitrided read only memory (NROM) cells 102, wherein the memory cells 102 are arranged in rows 103 and columns 104, wherein in the following, all NROM memory cells 102 of a column 104 form one memory cell word “w”.

The NROM memory cells 102 of one row 103 are respectively connected to a read circuit 105 via read lines 106. The read circuit 105 is connected to a multiplicity of sense amplifiers 107 by means of sense amplifier lines 108, wherein each one of the sense amplifiers 107 is respectively connected to the NROM memory cells 102 of a respective one of the rows 103 with a first of its inputs and to a reference unit providing a reference current with a second of its inputs.

The sense amplifiers 107 are connected via its respective outputs to a databus 109 by means of databus lines 110.

Furthermore, a memory region 111 is coupled to the read circuit 105, for storing the bit-level mask, as will be described below in more detail.

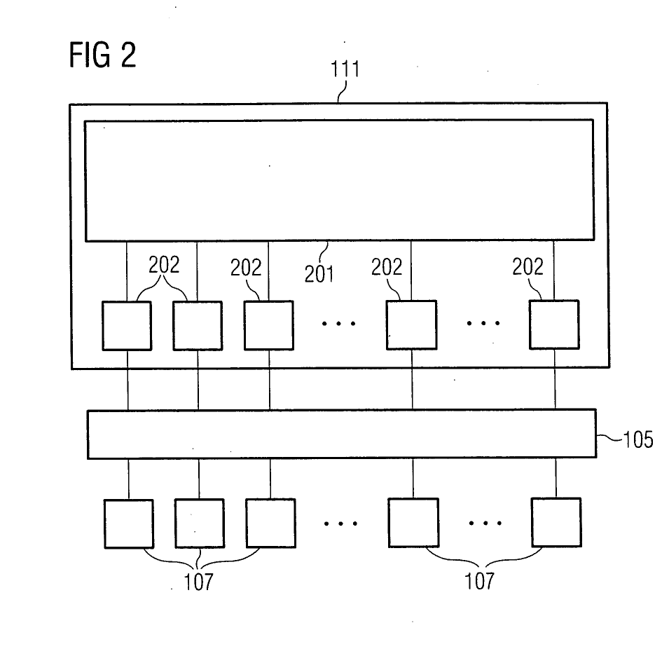

FIG. 2 illustrates the memory region 111 for storing the bit-level mask in detail. In accordance with this exemplary embodiment of the invention, the memory region 111 comprises a static random access memory (SRAM) 201, wherein a plurality of SRAM cells is provided, wherein the number of SRAM cells in the SRAM cell array 201 corresponds to the number of NROM memory cells 102 in the memory cell array 101. Each SRAM cell in the SRAM cell array 201 is assigned to a corresponding NROM memory cell 102 of the memory cell array 101.

Furthermore, the memory region 111 comprises a multiplicity of flipflops or latches 202, wherein the number of flipflops or latches 202 corresponds to the number of provided sense amplifiers 107.

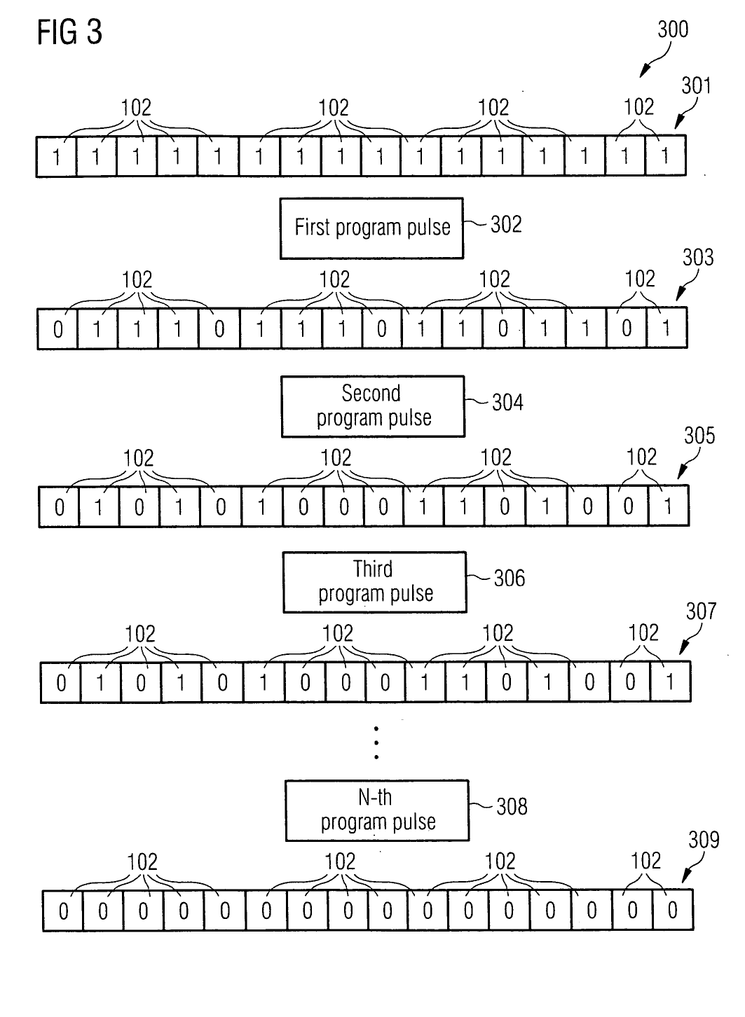

FIG. 3 shows a block diagram 300 illustrating the general exemplary idea in accordance with the present invention, wherein a word “w” of memory cells to be programmed is shown in an initial programming state 301, in which all NROM memory cells 102 of the respective memory cell word “w” are free of charge carriers in the oxide layer arrangement and therefore all have a low threshold voltage, corresponding to a logic value “1”, as shown in FIG. 3.

In a program operation, a first program pulse (step 302) is executed on the memory cell word “w” by raising the electrical voltage at the respective word line to activate the respective NROM memory cells 102 to be programmed (corresponding to a logic value “0” as shown in FIG. 3).

After having finished the application of the program pulse, it is assumed in this exemplary embodiment that some of the NROM memory cells 102 are programmed, i.e., some of the NROM memory cells 102 have been provided with enough electrons in their ONO (silicon oxide-silicon nitride-silicon oxide) layer arrangement by means of the first program pulse, so that their threshold voltage has been raised sufficiently over a predetermined minimum program threshold voltage. If the respective NROM memory cell 102 is programmed and thus has a high threshold voltage, which corresponds to a logic state “0” as shown in FIG. 3, no current flows through the respective memory cell 102 and the bit line.

FIG. 3 shows the state 303 of the NROM memory cells 102 of the memory cell word “w” after the application of the first program pulse 302.

As can be seen from FIG. 3, only some of the NROM memory cells 102 to be programmed already have a sufficiently high threshold voltage after the first program pulse and there are still many NROM memory cells 102 with a too low threshold voltage and those are therefore considered to be non-programmed.

Therefore, a second program pulse is applied to the yet non-programmed NROM memory cells 102 as will be shown and described in more detail below, symbolized in FIG. 3 by means of block 304.

After the application of the second program pulse 304, it is assumed that even more NROM memory cells 102 have a sufficiently high threshold voltage and are therefore considered to be programmed.

The status of the memory cell word after the application of the second program pulse is shown in FIG. 3 and denoted with reference numeral 305.

Since there are still not all NROM memory cells 102 of the memory cell word “w” programmed yet, a third program pulse is applied to the NROM memory cells 102 (block 306), which results in even more programmed NROM memory cells 102 as denoted with reference numeral 307.

In accordance with this exemplary embodiment of the invention, a predetermined number of program pulses is successively applied to the NROM memory cells 102 or alternatively as many program pulses are applied to the NROM memory cells 102 of the memory cell word “w” as necessary (in FIG. 3 illustrated with block 308), so that all NROM memory cells of the memory cell word “w” are programmed, in other words, show a sufficiently high threshold voltage (denoted with reference numeral 309).

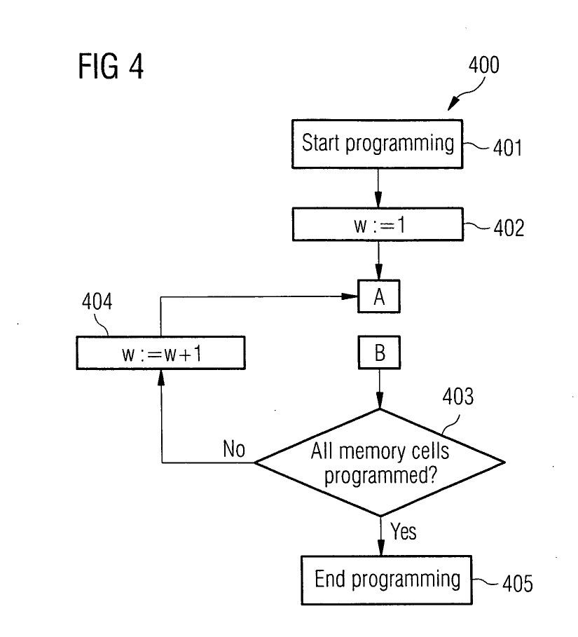

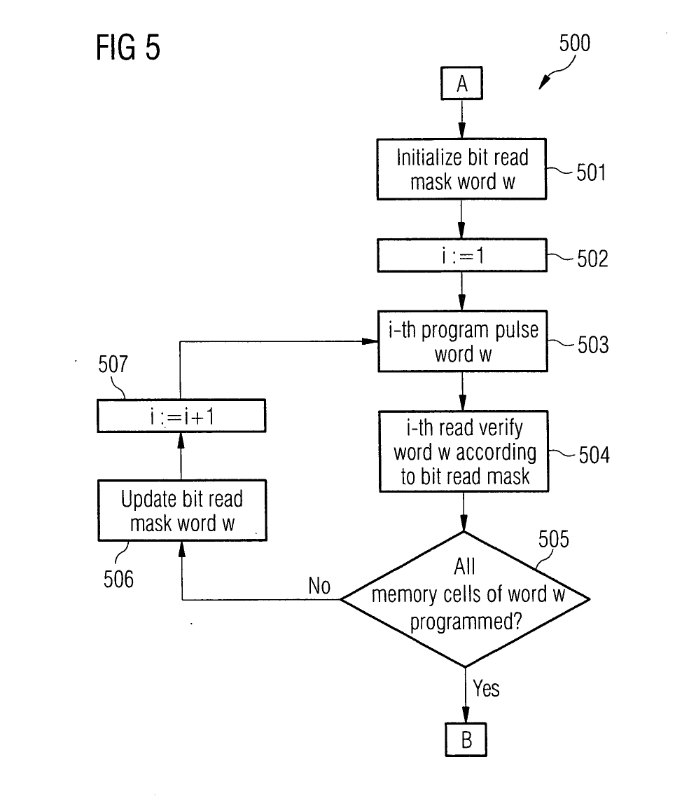

In the following, the process flow of an exemplary programming operation, that is executed on the NROM memory cells 102 of the memory cell array 101, will be described with reference to the process flow diagrams 400 (as shown in FIG. 4) and 500 (as shown in FIG. 5).

After having started the programming operation (start step 401) a memory cell word index “w” is set to an initial value, in accordance with this embodiment of the invention, the memory cell word index “w” is set to the value “1” (step 402).

Then, a programming operation (A) is applied on the respective memory cell word “w” as shown in the process flow diagram 500 in FIG. 5 and which will be described in more detail below.

After the programming operation has been applied on the respective memory cell word, which is assigned by the memory cell word index “w” (B), it is determined as to whether all memory cells 102 of the memory cell array 101 has now been programmed (determination step 403).

In case that all memory cells have already been programmed (“No” in step 403), the memory cell word index “w” is increased by the value “1” (step 404) and the program pulse operation for the next memory cell word “w+1” will be executed as shown in FIG. 5.

However, if all NROM memory cells 102 of the memory cell array 101 are programmed (“Yes” in determination step 403) the programming operation is finished and the process flow enters into the end programming step 405.

FIG. 5 illustrates the process flow of the programming operation being applied to each memory cell word “w”.

As shown in FIG. 5, in a first step, a bit-level mask for memory cell word “w” is initialized (step 501), in accordance with this exemplary embodiment of the invention by initializing a bit-level mask in the SRAM 201 to a predetermined value, for example to a logic “1”, representing that all NROM memory cells 102 of the memory cell array 101 have to be programmed.

In the next step, a program pulse index “i” is initialized (step 502) to a predetermined value, in accordance with the present embodiment of the invention to the value “1”.

In the next step, (the first, generally speaking i-th) program pulse (step 503), is applied to the NROM memory cells 102 of the memory cell word “w”.

After having applied the i-th program pulse for the NROM memory cells 102 of the memory cell word “w”, a program verify read operation is carried out to the NROM memory cells 102 of memory cell word “w” according to the stored bit-level mask, in a first iteration, to all NROM memory cells 102 of the memory cell word “w,” which are to be programmed (step 504).

Then, it is determined as to whether all NROM memory cells 102 of the memory cell word “w” are programmed (step 505) and in case that not all NROM memory cells 102 of the memory cell word “w” are programmed (“No” in step 505), the bit-level mask (bit-read mask) of memory cell word “w” is updated (step 506) by changing the state of the memory cells of the SRAM 201, such that those memory cells of the SRAM 201 being assigned to already programmed NROM memory cells 102 of the memory cell word “w” as determined in the determination step 505, are changed to a logic value “0”.

Then, the program pulse index “i” is increased by a value “1” (step 507) and the process flow is continued in step 503, in other words, a next programming iteration is carried out. In each program pulse iteration, a program pulse is applied to the not yet programmed memory cells and a verify read operation is performed on the not yet programmed NROM memory cells 102 of the memory cell word “w,” in accordance of the respectively updated bit level mask of memory cell word “w”.

This process loop is repeated until it is determined in step 505 that all memory cells 102 of the memory cell word “w” are programmed (“Yes” in step 505).

Thus, this method achieves a reduction of power consumption during verify reads in the memory cell array 101. However, it should be noted that in other embodiments of the invention, this method could be applied also to an erase verify read operation or to a depleted verify operation to verify as to whether the memory cells of a memory cell array are all erased or depleted, respectively.

The above-described exemplary embodiment of the invention can be summarized in that in a verify read operation, the device checks whether a bit reached its final desired level (during a read operation). These read operations are carried out to a full page every time according to the prior art. However, some of the bits in a page are already verified, but in accordance to the prior art, they are also re-checked. This consumes time and power. The idea in accordance with the above-described embodiment is to skip the verify read operation of bits that are already verified from previous verify read operations, which leads to a power consumption reduction and a time reduction.

In this context, it should be noted that a desired group of memory cells 102 can be subject of a verify read, that is a memory cell word can be verified together or the memory cells 102 of a full memory cell page, a predetermined number of memory cells 102 of a memory cell array 101 all grouped into, can be subject of one program pulse iteration.

In the following, additional embodiments of the invention will be described.

With regard to the following embodiments, it is assumed, that not all memory cells achieve the desired status at the same time. Those memory cells, which already have achieved the desired status, however, do not need to be read in future iterations. This means, that the number of the sense amplifiers being working at the same time is decreased in each iteration, which leads to power saving. By means of additional electronic circuits, the performance can be increased by addressing only those memory cells via the sense amplifier, the status of which have not achieved the desired (target) status. All other cells are clearly skipped, which leads to an acceleration of the entire read operation.

In this context, it is to be mentioned that either the sense amplifiers of their respective memory cells that do not need to be read, may be deactivated or other or all components usually involved in the read/verify operation and being implemented in the read circuit 105 may be deactivated in accordance with the stored bit-level mask.

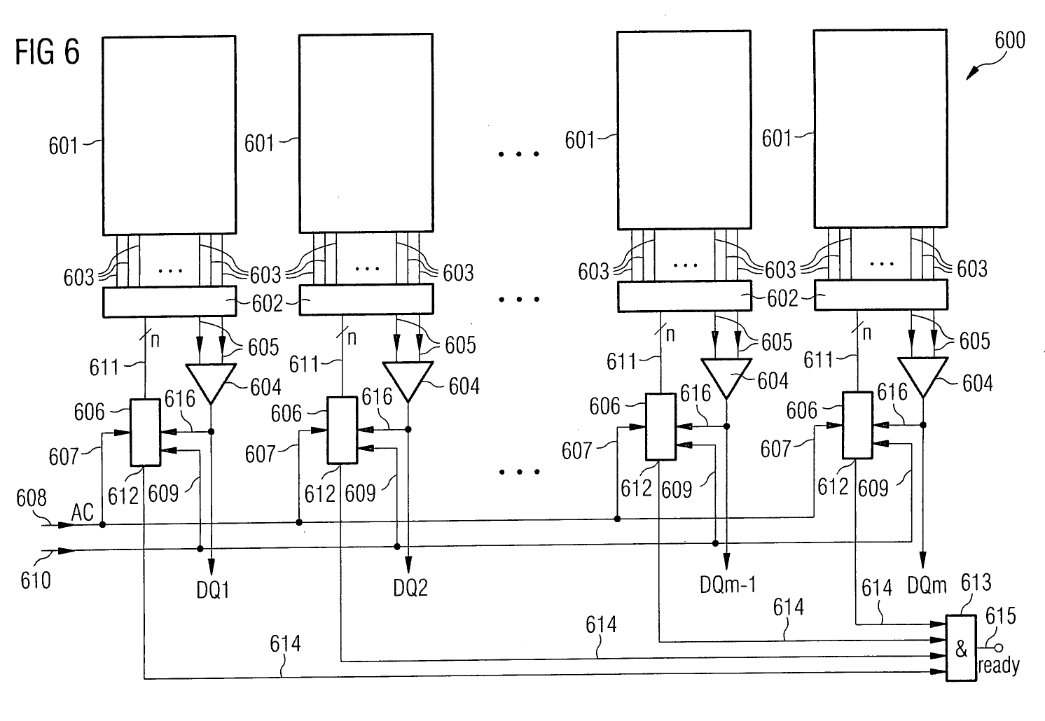

FIG. 6 shows a portion of a memory circuit arrangement 600 in accordance with another exemplary embodiment of the invention.

The portion 600 in accordance to FIG. 6, comprises a plurality of memory cell arrays 601, each memory cell array 601 comprising a plurality of non-volatile memory cells, for example flash memory cells like floating gate memory cells or NROM memory cells, which may be arranged in rows and columns in matrix form in each memory cell array 601.

The memory cells of each column of each memory cell array 601 are respectively connected to a bit line decoder 602 by means of bit lines 603.

Each bit line decoder 602, wherein one bit line decoder 602 is provided for each memory cell array 601, is provided with a sense amplifier 604. In case that 64 to 256 memory cell arrays 601 are provided in the memory circuit arrangement 600, 64 to 256 sense amplifiers 604 are provided, respectively.

The inputs 605 of the sense amplifier are connected to the outputs of the bit line decoder 602 and the output of each sense amplifier 604 is coupled to a data bus (not shown) and provides data signals DQ1, DQ2, DQₘ₋₁, DQₘ, respectively, thereto.

Furthermore, one bit line address generator unit 606 is provided for each memory cell array 601, wherein a first input 607 of the bit line address generator unit 606 is connected to an address counter line 608, by means of which the bit line address generator unit 606 is connected to an address counter unit (not shown), which generates the respective address of the memory cells to be read.

Furthermore, a second input 609 of the bit line address generator unit 606 is coupled to a mask data line 610, which is connected to a mask data generation unit (not shown) providing mask data information, for example the data for mask data.

Further, the output of the bit line decoder 602 is coupled to a third input 615 of the bit line address generator unit 606.

The bit line address generator unit 606 is adapted to generate only those bit addresses of those memory cells in the respective memory cell array 601 that still have to be read. The bit line address generator unit 606 is coupled to an input of the bit line decoder 602 by means of n bit line address lines 611, wherein n denotes the bit line address depth. A second output 612 of each bit line address generator unit 606 is coupled to an AND gate 613 by means of a ready line 614. The bit line address generator unit 606 generates a signal logic “1” in case all memory cells of their respective memory cell array 601 have been read and/or verified, thereby indicating that the entire memory cell array 601 has been completely read and/or verified.

Thus, in case that all bit line address generator units 606 indicate that they have read/verified all memory cells of its respective memory cell array 601, the AND gate 613 provides a high level ready signal 615, thereby indicating that the read/verify operation has been performed from all memory cells of all memory cell arrays 601 in the memory circuit arrangement 600.

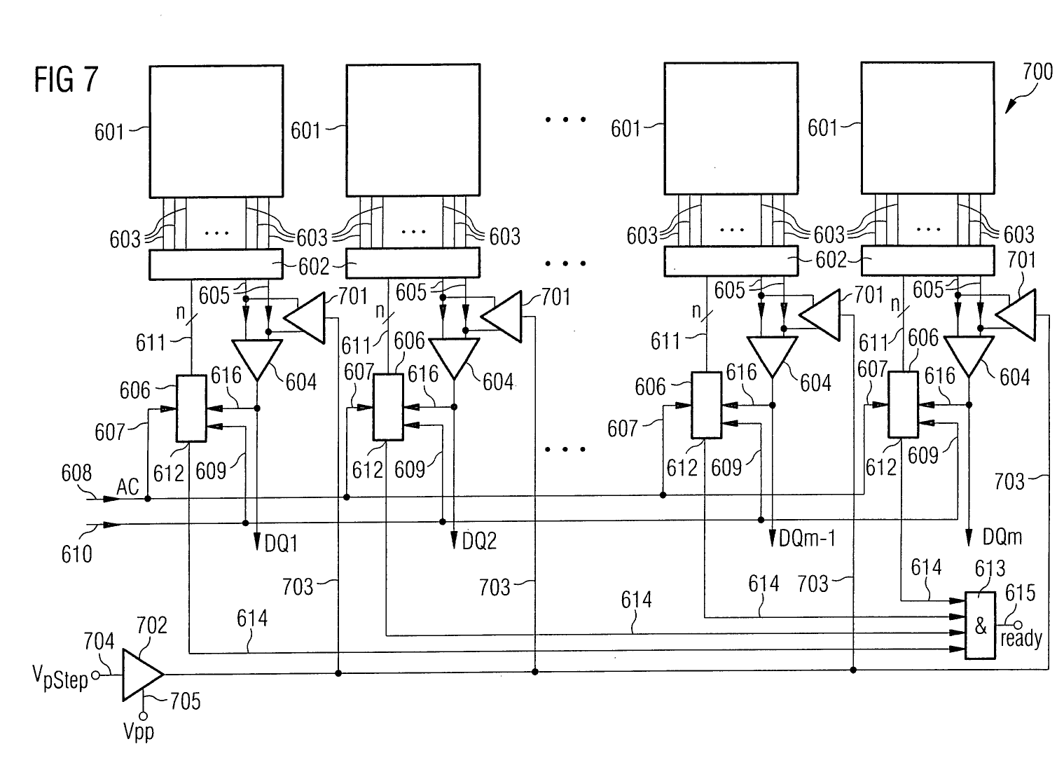

FIG. 7 shows a portion 700 of a memory circuit arrangement in accordance with another embodiment of the present invention, wherein this portion 700 of the memory circuit arrangement in accordance with FIG. 7 differs from the memory circuit arrangement in accordance with FIG. 6, in that it is furthermore capable for program operation. For this additional capability, the memory circuit arrangement 700 in accordance with FIG. 7 additionally comprises a bit line driver unit 701 for each memory cell array 601, wherein an input of each bit line driver 701 is connected to a voltage regulator for providing a program pulse 702 via bit line driver input lines 703.

A data input of the voltage regulator unit 703 is connected to a first terminal 704, at which a programming step voltage V_{pStep} can be applied representing a voltage in accordance with the respective programming step.

A second terminal 705 of the voltage regulator unit 702 is connected to, for example, a charge pump (not shown) or a booster circuit (not shown) and receives the respectively required programming voltage Vₚₚ for programming the memory cells of the respective memory cell arrays 601.

The bit line drivers 701 are adapted to provide the respective program pulses to the sense amplifier lines 605 and via those to the bit line decoder 602 and thereby to the respective memory cells of the memory cell array 601, which are to be programmed.

The further unit of the memory circuit arrangement 700 are similar to those components of the memory circuit arrangement 600 as shown in FIG. 6 and are therefore not described here again.

By means of the memory circuit arrangement in accordance to FIG. 6 and FIG. 7, a simultaneous improvement of the performance and power consumption is achieved by clearly modifying the sense amplifier and the bit line decoder.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A memory circuit arrangement, comprising
a memory cell array comprising a plurality of memory cells; and
a memory read/verify control circuit for controlling a read operation and/or a verify operation on one or more memory cells of the memory cell array, wherein the memory read/verify control circuit is adapted to read and/or verify the status of each memory cell of the memory cell array according to read and/or verify instruction information on memory cell level.

2. The memory circuit arrangement of claim 1, further comprising a determination unit for determining the memory cells, upon which the read operation and/or the verify operation should be performed.

3. The memory circuit arrangement of claim 1, wherein the read and/or verify instruction information comprises a bit-level mask including bits, wherein each bit of the bit-level mask is assigned to one memory cell of the memory cell array, and wherein each bit represents the information as to whether or not the status of the assigned memory cell should be read and/or verified.

4. The memory circuit arrangement of claim 3, further comprising a memory region for storing the read and/or verify instruction information.

5. The memory circuit arrangement of claim 4, wherein the memory cell array comprises a flash memory cell array.

6. The memory circuit arrangement of claim 4, wherein the memory region comprises a random access memory.

7. The memory circuit arrangement of claim 6, wherein the memory region comprises a static random access memory.

8. The memory circuit arrangement of claim 1, further comprising a plurality of amplifier circuits coupled to the memory cells of the memory cell array for amplifying signals read from the memory cells.

9. The memory circuit arrangement of claim 8, wherein the amplifier circuits comprise sense amplifier circuits, wherein each sense amplifier circuit is assigned to one or a predetermined number of memory cells in the memory cell array.

10. The memory circuit arrangement of claim 8, wherein:
the memory cells are arranged in columns and rows within the memory cell array; and
each amplifier circuit is respectively assigned to all memory cells of one row or to all memory cells of one column.

11. The memory circuit arrangement of claim 8, further comprising a plurality of storage elements, wherein each storage element is assigned to one amplifier circuit, and wherein each storage element stores a portion of the read and/or verify instruction information on the memory cell level.

12. The memory circuit arrangement of claim 11, wherein the storage elements are arranged as latches or as flip-flops.

13. The memory circuit arrangement of claim 1, wherein the memory cell array comprises a flash memory cell array.

14. The memory circuit arrangement of claim 13, wherein the memory cells comprise NROM cells.

15. A method for reading and/or verifying the status of memory cells of a memory cell array, the method comprising:
receiving a read and/or verify instruction information that identifies memory cells of the memory cell array on memory cell level that are to be read and/or verified; and
reading and/or verifying the identified memory cells of the memory cell array according to the read and/or verify instruction information.

16. The method of claim 15, further comprising:
a) executing a programming step on the memory cells of the memory cell array according to a programming instruction;
b) executing a verification step on the memory cells of the memory cell array, thereby determining the memory cells that are sufficiently programmed in the programming step;
c) storing the determined memory cells in the read and/or verify instruction information;
d) executing an additional programming step on the memory cells of the memory cell array according to the programming instruction;
e) executing an additional read and/or verification step on the memory cells of the memory cell array only on the memory cells that are not yet sufficiently programmed according to the read and/or verify instruction information, thereby determining the memory cells which are sufficiently programmed in the additional programming step.

17. The method of claim 16, wherein:
steps d) and e) are repeatedly executed; and
the read and/or verify instruction information is updated after each additional read and/or verification step.

18. A memory circuit arrangement, comprising
a memory cell array comprising a plurality of memory cells; and
means for controlling a read operation and/or a verify operation on one or a plurality of memory cells of the memory cell array, wherein the means for controlling is adapted to read and/or verify the status of each memory cell of the memory cell array according to read and/or verify information on memory cell level.

19. The memory circuit arrangement of claim 18, wherein the read and/or verify information comprises a bit-level mask including bits, wherein each bit of the bit-level mask is assigned to one memory cell of the memory cell array, respectively, and wherein each bit represents the information as to whether or not the status of the assigned memory cell should be read and/or verified, the arrangement further comprising a memory region for storing the bits of the bit-level mask.

20. The memory circuit arrangement of claim 1, wherein the memory cell array comprising a plurality of memory cells comprises a flash memory cell array comprising a plurality of flash memory cells.
